(19) United States
(12) Patent Application Publication
(10) Pub. No.: US 2004/0020046 A1
(43) Pub. Date: Feb. 5, 2004

(54) Production method for conductive paste and production method for printed circuit

(76) Inventors: Takeshi Suzuki, Osaka (JP); Satoru Tomekawa, Osaka (JP); Yosihiro Tomita, Osaka (JP); Yuichiro Sugita, Osaka (JP); Shigeru Yamane, Osaka (JP)

Correspondence Address: Merchant & Gould, P O Box 2903, Minneapolis, MN, 55402-0903, US

(21) Appl. No.: 10/433,938

(22) PCT Filed: Aug. 8, 2002
(86) PCT No.: PCT/JP02/08094

(30) Foreign Application Priority Data
Aug. 9, 2001 (JP) 2001-242858

(51) Int. Cl. H05K 3/10; H01M 2/16

(52) U.S. Cl. 29/852; 29/846; 429/134

(57) ABSTRACT

The present invention provides a method for manufacturing a conductive paste. The method includes deforming conductive particles so that a deformation degree is 1.01 to 1.5 by application of a stress to the conductive particles and mixing the deformed conductive particles with a binder that includes a thermosetting resin as the main component. The deformation degree is determined by dividing an average diameter of the conductive particles after deformation by an average diameter of the conductive particles before deformation, where the average diameter is measured by a laser diffraction method. The use of this conductive paste for a prepreg sheet having limited compressibility can suppress a short circuit between via holes and the degradation of insulation properties.

### TECHNICAL FIELD

The present invention relates to a method for manufacturing a conductive paste and a printed wiring board. This conductive paste is suitable for a paste that is filled in via holes to connect wiring patterns between the layers of a multilayer wiring board.

### BACKGROUND ART

With a growing demand for compact and high-density electronic equipment, a printed wiring board on which electronic components can be mounted with high density has been developed.

In printed wiring boards, an inner via hole connection with a conductive paste is proposed instead of conventional plated through holes, which have been prevented high-density wiring (e.g., JP 6(1994)-268345 A). This connection efficiently can provide a high-density printed wiring board.

The high-density printed wiring board is manufactured in the following manner. First, a release film (polymer film) having release properties is attached to both surfaces of a compressible porous prepreg sheet (insulating substrate), and through holes are formed in the prepreg sheet. Then, the through holes are filled with a conductive paste, and the films are removed. Subsequently, a metal foil is attached to both surfaces of the prepreg sheet, which then is heated and pressed to make an electrical connection between the metal foils by a via hole conductor (i.e., the conductive paste after being cured). Moreover, the metal foils are etched selectively to form a circuit.

This manufacturing method will be described in detail by referring to the drawings.

As shown in FIG. 6A, a porous prepreg sheet 12 with a release film 11 attached to both surfaces is prepared. The prepreg sheet 12 is, e.g., a composite material obtained by impregnating an aromatic polyamide nonwoven fabric with an epoxy resin.

Next, as shown in FIG. 6B, through holes 13 are formed at predetermined positions of the prepreg sheet 12 by irradiation of an energy beam such as a laser beam. As shown in FIG. 6C, using the table of a printing press (not shown), a conductive paste 14 is applied to the prepreg sheet 12 from the upper side of the release film 11 so as to fill the through holes 13. At this time, the release film 11 acts as a film for protecting the prepreg sheet 12 from contamination.

As shown in FIG. 6D, the release films 11 are removed. Then, as shown in FIG. 6E, a metal foil 15, e.g., a copper foil is attached to both surfaces of the prepreg sheet 12. The metal foils 15 are pressed against the prepreg sheet 12 while applying heat, so that the prepreg sheet 12 is compressed. Consequently, as shown in FIG. 6F, the metal foils 15 adhere to the prepreg sheet 12, and the compression of the prepreg sheet 12 makes an electrical connection between the metal foils via the through holes 13 filled with the conductive paste 14 (i.e., the via hole connection). At the same time, the epoxy resin contained in the prepreg sheet 12 and the conductive paste 14 are cured.

Thereafter, as shown in FIG. 6G, the metal foils 15 on both surfaces of the prepreg sheet 12 are etched selectively to form wiring patterns 16, thus producing a printed wiring board.

However, the above manufacturing method has the following problems.

As shown in FIG. 7A, a nonwoven fabric 17 that is impregnated with a thermosetting resin by laminating often is used as the prepreg sheet 12. Therefore, the prepreg sheet 12 is in a semi-rigid state before heating (e.g., JP 7 (1995)-106760 A). Generally, there are some recesses 18 in the surface of the prepreg sheet 12 due to the nonwoven fabric 17 exposed to or in the vicinity of the surface. These recesses 18 remain as gaps between the release films 11 and the prepreg sheet 12.

When the through holes 13 are filled with the conductive paste 14 and the prepreg sheet 12 is compressed while leaving the recesses 18, as shown in FIG. 7B, the conductive paste 14 may enter the recesses 18 to form a short-circuit portion 20 between adjacent via holes or to degrade the insulation reliability between wirings.

In particular, the short circuit between via holes easily occurs in a high-density printed wiring board because the via holes also are formed with high density.

To achieve good electrical conduction between wiring layers, a high-density printed wiring board uses the compressible prepreg sheet 12 in which pores 19 are dispersed, as shown in FIG. 7A. However, the conductive paste 14 also may flow into those pores 19. Therefore, like the recesses 18, a short circuit caused by the pores 19 increases as the density of wiring patterns becomes higher.

One possibility for solving the above problems is to suppress the recesses 18 by smoothing the surface of the prepreg sheet 12. Another possibility is to reduce the pores 19 in the prepreg sheet 12. However, such prepreg sheets have poor compressibility, so that the conductive paste filled in the through holes cannot be compressed sufficiently. This makes it difficult to ensure good electrical conduction between the wiring layers.

### DISCLOSURE OF INVENTION

Therefore, with a forgoing in mind, the present invention provides a method for manufacturing a conductive paste. The method includes deforming conductive particles so that a deformation degree is 1.01 to 1.5 by the application of a stress to the conductive particles and mixing the deformed conductive particles with a binder that includes a thermosetting resin as the main component.

Here, the deformation degree (R₂/R₁) is determined by dividing an average diameter R₂ of the conductive particles after deformation by an average diameter R₁ of the conductive particles before deformation, where the average diameter is measured by a laser diffraction method.

The conductive paste of the present invention makes it easier to establish a good interlayer connection. Therefore, a low substrate resistance can be achieved easily, even if the conductive paste is used for a prepreg sheet having poor compressibility.

The present invention also provides a method for manufacturing a printed wiring board. The method includes producing a conductive paste according to the present invention; forming through holes in a prepreg sheet with a release film attached to at least one surface; filling the through holes with the conductive paste; compressing the prepreg sheet along with the release film and the conductive paste; and removing the release film from the prepreg sheet after compressing the prepreg sheet.

It is preferable that the prepreg sheet includes a reinforcing fiber and a resin, a resin layer that includes no reinforcing fiber is formed on the surface of the prepreg sheet, and the resin layer has a thickness of 1 μm to 30 μm before compressing the prepreg sheet.

### BRIEF DESCRIPTION OF DRAWINGS

FIG. 1 shows a scanning electron microscope (SEM) observation of an example of deformed conductive particles.

FIG. 2 shows a SEM observation of another example of deformed conductive particles.

FIG. 3 shows a SEM observation of yet another example of deformed conductive particles.

FIG. 4 shows a SEM observation of an example of conductive particles before being deformed.

FIGS. 5A to 5F are cross-sectional views showing an example of a method for manufacturing a printed wiring board of the present invention.

FIGS. 6A to 6G are cross-sectional views showing a method for manufacturing a conventional printed wiring board.

FIGS. 7A and 7B show a short circuit in a conventional printed wiring board. FIG. 7A illustrates recesses and pores in the conventional printed wiring board. FIG. 7B illustrates a short circuit caused by the recesses.

### EMBODIMENTS OF THE INVENTION

In a laser diffraction method, the diameters of particles are measured by a laser beam that projects the particles. Therefore, when a particle is made flat, the particle diameter to be measured increases even if the particle has the same volume. The present invention uses the deformation degree to determine the deformation of conductive particles, and the conductive particles are flattened so that the deformation degree is 1.01 to 1.5, and preferably 1.02 to 1.30, by the application of a stress to the conductive particles. The flattening of the conductive particles results in a larger contact area between the particles, which in turn reduces the substrate resistance.

It is preferable that the deformed conductive particles have a specific surface area of 0.05 m²/g to 1.5 m²/g. The viscosity of a conductive paste increases with an increase in specific surface area. When the viscosity is excessively high, it is difficult to fill the through holes with the conductive paste. Moreover, the paste at both ends of a through hole sticks to the release films and may be peeled off together during removal of the films, which is so called a “paste deficiency.” In view of this, the preferred specific surface area is less than 1.0 m²/g.

It is preferable that the conductive particles are deformed so that the average diameter measured by the laser diffraction method is 0.2 μm to 20 μm. When the average diameter is less than 0.2 μm, it is difficult to achieve a specific surface area of not more than 1.5 m²/g. Therefore, the paste viscosity becomes too high for the conductive particles to be dispersed with high concentration. When the average diameter is more than 20 μm, the number of conductive particles filled in one via hole is reduced. A small number of conductive particles makes it impossible to provide a sufficiently low substrate resistance because of a decrease in contact area between the particles.

The conductive particles with a specific surface area of less than 0.05 m²/g have a large average diameter. Therefore, it is difficult to achieve a low substrate resistance for the same reason as described above.

The conductive paste includes the conductive particles and a binder that includes at least a thermosetting resin as the main component. In the conductive paste, 30 to 70 vol % of conductive particles may be mixed with 70 to 30 vol % of a binder. For this mixing ratio, the preferred viscosity of the conductive paste is not more than 1000 Pa·s.

It is preferable that the conductive particles include at least one selected from the group consisting of gold, platinum, silver, palladium, copper, nickel, tin, lead, indium, zinc, and chromium, and particularly at least one selected from the group consisting of gold, platinum, silver, palladium, copper, nickel, tin, lead, and indium. The conductive particles may be any one of the following groups (I) to (IV):

(I) gold, platinum, silver, palladium, copper, nickel, tin, lead, or indium;

(II) alloy particles obtained by any combination of gold, platinum, silver, palladium, copper, nickel, tin, lead, indium, zinc, and chromium;

(III) particles including conductive or non-conductive particles as nuclei, which are coated with at least one metal selected from gold, platinum, silver, palladium, copper, nickel, tin, lead, and indium; and

(IV) particles including conductive or non-conductive particles as nuclei, which are coated with an alloy obtained by any combination of gold, platinum, silver, palladium, copper, nickel, tin, lead, indium, zinc, and chromium.

A process of deforming the conductive particles will be described below.

There is no particular limitation to the device used for deformation of the conductive particles as long as it can apply a mechanical stress, and mills, e.g., a ball mill or jet mill may be used. In the case of a mill, the deformation degree can be controlled under various conditions of the diameter and the amount of ceramic balls, the rotation speed of the ball mill, the process time, etc.

It is preferable that the deformation process is performed while protecting the conductive particles from oxygen and moisture. This is because the viscosity of the conductive paste is raised by oxygen and moisture that are present on the surface of the conductive particles. The viscosity rise due to oxygen and moisture is considered to result from an increase in the amount of binder resin absorbed by the particle surface or a closslinking reaction of the binder resin with water molecules.

Therefore, it is preferable that the conductive particles are deformed, e.g., in a nonaqueous solvent, and specifically in an organic solvent. The organic solvent can be alcohol such as ethanol. If necessary, a non-oxidizing gas such as nitrogen may be blown in the organic solvent to reduce the dissolved oxygen. A suitable amount of dissolved oxygen in the organic solvent is 1 mg/L. Moreover, it is preferable to maintain a non-oxidizing atmosphere in the mill where the atmosphere is in contact with the solvent. Examples of the non-oxidizing atmosphere include the atmosphere of a reduced pressure and the atmosphere of a non-oxidizing gas such as nitrogen and inert gas. To suppress the absorption of oxygen and water, it is preferable that the deformation of the conductive particles takes as a short time as possible.

The study conducted by the present inventors showed that the paste viscosity was reduced preferably when water absorbed by the surface of the conductive particles was not more than 1000 ppm, and the oxygen concentration on the surface of the conductive particles was not more than 1.0 wt %.

It is preferable further to include a process of drying the conductive particles to decrease the concentration of oxygen or absorbed water on the surface of the conductive particles. The drying process may be performed in the non-oxidizing atmosphere as described above. A suitable atmosphere temperature for the drying process is 50° C. to 200° C. The drying process may be performed before or after the deformation process. If necessary, it may be performed before and after the deformation process.

The conductive particles before deformation are not particularly limited and can be substantially spherical in shape. Strictly speaking, when a particle has a substantially spherical shape, the ratio of the longest diameter to the shortest diameter of the particle is in the range of 1 to 2.0, and preferably in the range of 1 to 1.5. The substantially spherical shape includes a perfect sphere.

When the specific surface area of the deformed conductive particles is excessively large, the surface of the conductive particles may be smoothed before deformation. The above deformation process also serves to smooth the surface of the conductive particles to some extent, since the conductive particles come into contact with one another. However, if sufficient smoothness is not achieved, a process of smoothing the conductive particles can be performed beforehand by using a powder disperser such as a kneader or planetary mixer. Like the deformation process, it is preferable that the conductive particles are smoothed in the nonaqueous solvent and the non-oxidizing atmosphere (e.g., the atmosphere of a non-oxidizing gas).

As described above, the conductive particles may be subjected appropriately to the drying process, the smoothing process, etc. before and after the deformation process. Moreover, a cracking (disintegration) process also can be performed to separate the aggregated particles after deformation. The conductive particles are produced, e.g., by performing drying, deformation, redrying, and cracking in sequence. During these processes, it is preferable to maintain a non-oxidizing atmosphere (e.g., a nitrogen atmosphere) as a gaseous phase in contact with the conductive particles.

The conductive paste of the present invention allows for a printed wiring board having a sufficiently small resistance between the wiring layers, even if the compressibility of the prepreg sheet is limited to avoid a short circuit between the wirings. This is because a contact area between the conductive particles is increased by flattening the particles. Conventionally known conductive particles include so-called scale-shaped conductive particles produced by an electrolytic method. These conductive particles are in the form of dendrite due to the electrolytic method and have an excessively large specific surface area. Thus, the viscosity of the conductive paste increases to easily cause a deficiency of conductive paste filled in the through holes or a defect in which the conductive paste sticks to the release films and is peeled off together during removal of the films.

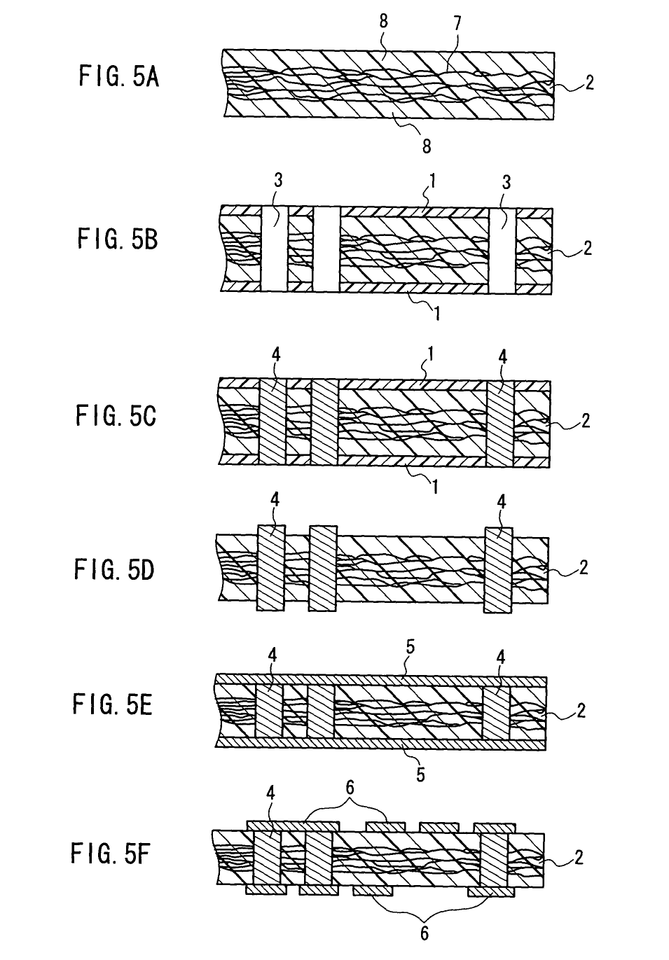

A preferred example of a method for manufacturing a printed wiring board will be described by referring to FIGS. 5A to 5F.

FIG. 5A shows a prepreg sheet 2 that includes a reinforcing fiber 7 and a resin layer 8. The reinforcing fiber 7, e.g., an aramid fiber is concentrated inside the sheet. The resin layer 8 consists substantially of a resin component and is formed on both surfaces of the sheet. Since no fiber is contained in the resin layer, fewer recesses that cause a short circuit are generated in the surface of the prepreg sheet 2. The thickness of the resin layer is preferably 1 to 30 μm, and particularly 5 to 15 μm. The surface roughness Ra of the prepreg sheet 2 is preferably not more than 10 μm. The whole thickness of the prepreg sheet 2 is not particularly limited, and preferably 50 to 150 μm.

For this prepreg sheet 2, the inner pores as well as the recesses may be reduced or completely eliminated. The conventional spherical conductive particles cannot ensure sufficient electrical conduction under the limited compressibility. However, the conductive particles of the present invention can achieve a low substrate resistance, even if the compressibility of the prepreg sheet is small.

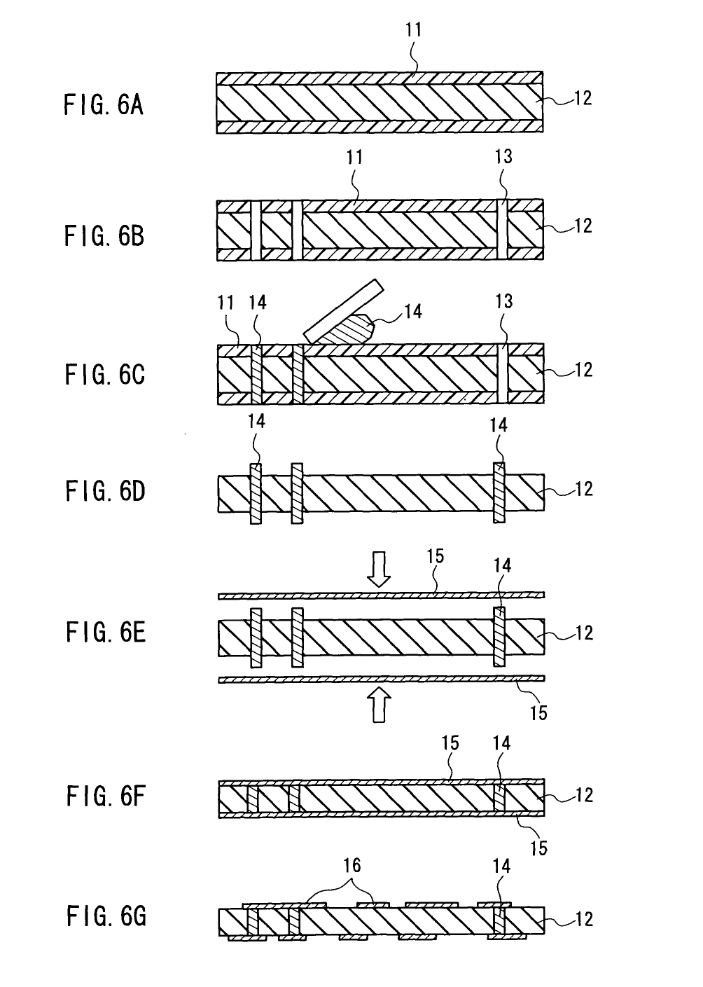

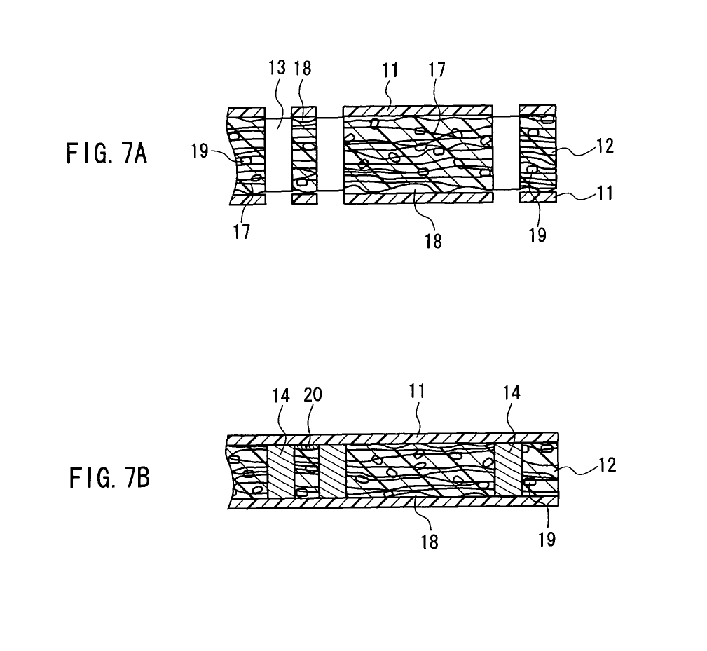

The processes shown in FIGS. 5B to 5F are basically the same as those in FIGS. 6C to 6G. Through holes 3 are formed in the prepreg sheet 2 with a release film 1 attached to both surfaces (FIG. 5B). The through holes 3 are filled with a conductive paste 4 (FIG. 5C). The release films 1 are removed (FIG. 5D). A metal foil 5 is attached to both surfaces of the prepreg sheet 2, and then the prepreg sheet 2 is compressed (FIG. 5E). Each of the metal foils 5 is patterned into a wiring pattern 6 (FIG. 5F).

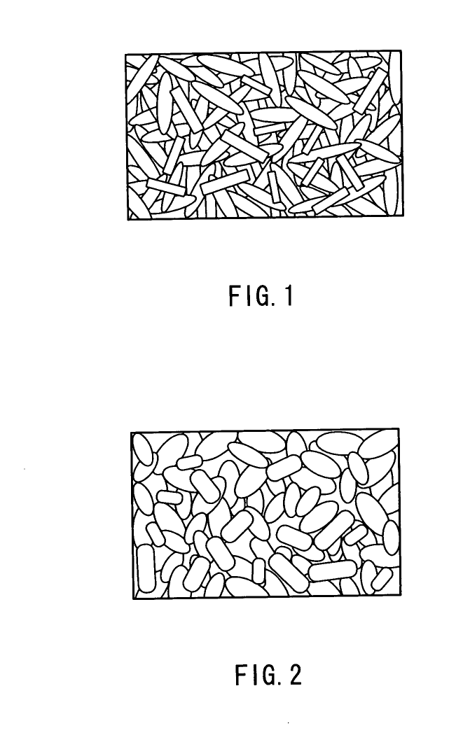

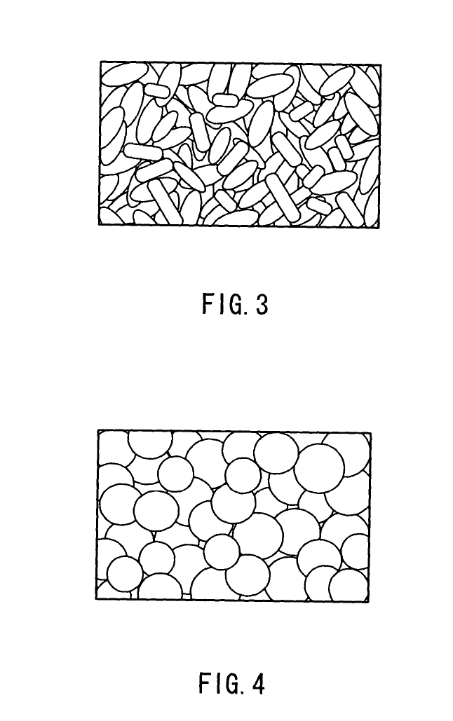

FIGS. 1 to 3 show the scanning electron microscope (SEM) observations of deformed copper particles. These particles were obtained by deforming substantially spherical copper particles (FIG. 4) so that the deformation degree was 1.20 for FIG. 1, 1.02 for FIG. 2, and 1.11 for FIG. 3. The copper particles in FIG. 4 were prepared in such a manner that copper was precipitated by a wet reaction, then smoothed, and sieved to control the particle size.

All the copper particles thus deformed were oval (similar to an oval gold coin in plan view) or took the form of a persimmon seed.

To obtain these copper particles, the substantially spherical copper particles, together with ethanol, were placed in a ball mill and deformed by ceramic balls. The deformation degree was adjusted by appropriately changing the rotation speed and time of the mill. The atmosphere in the ball mill was produced by nitrogen substitution during the deformation process.

A portion of the deformed copper particles was dispersed in water, and then the deformation degree was measured by the laser diffraction method using a “Microtrac HRA model 9320-100” (a laser wavelength of 780 nm and a laser output of 3 mW) manufactured by Nikkiso Co., Ltd. The remaining portion was used to prepare a conductive paste.

A binder was added to the deformed copper particles, and then was kneaded with a three-roller to provide a conductive paste. Specifically, 65 vol % of copper particles was mixed with 10 vol % of bisphenol F epoxy resin (“Epicoat 807” manufactured by Japan Epoxy Resins Co., Ltd.), 20 vol % of dimer acid diglycidyl ester epoxy resin (“Epicoat 871” manufactured by Japan Epoxy Resins Co., Ltd.), and 5 vol % of amine adduct curing agent (“Amicure MY-24” manufactured by Ajinomoto Co., Inc.). In this case, the bisphenol F epoxy resin and the dimer acid diglycidyl ester epoxy resin constituted an epoxy resin main ingredient.

A thermosetting resin used in the binder is not limited to the bisphenol F epoxy resin or the like and can be a glycidyl ether epoxy resin such as a bisphenol A epoxy resin and bisphenol AD epoxy resin, or an epoxy resin containing at least two epoxy groups such as an alicyclic epoxy resin, glycidyl amine epoxy resin, and glycidyl ester epoxy resin.

An epoxy compound containing one epoxy group also may be added to the epoxy resin main ingredient as a reactive diluent. In addition to the epoxy resin, a polyimide resin, a cyanate ester resin, or a phenol resol resin can be used as the main ingredient of the binder to produce a conductive paste.

The above conductive paste is a so-called solventless type. If necessary, however, additives such as a solvent or dispersing agent can be added to adjust the printing characteristics. Examples of the additives include butyl cellosolve, ethyl cellosolve, butyl carbitol, ethyl carbitol, butyl carbitol acetate, ethyl carbitol acetate, and α-terpineol.

A prepreg sheet was prepared along with the conductive paste. As shown in FIG. 5A, a reinforcing fiber (aramid fiber) was concentrated inside the sheet, and a resin layer that was made of epoxy resin and had a thickness of about 5 μm was formed on both surfaces of the sheet.

A fiber for reinforcing the prepreg sheet is not limited to the aramid fiber. Examples of the reinforcing fiber include organic fibers such as PBO (polyparaphenylene benzobisoxazole) fibers, PBI (polybenzimidazole) fibers, PTFE (polytetrafluoroethylene) fibers, PBZT (polyparaphenylene benzobisthiazole) fibers and all aromatic polyester fibers, or inorganic fibers such as glass fibers. Instead of the epoxy resin, a thermosetting resin such as a polyimide resin, a phenol resin, a fluorocarbon resin, an unsaturated polyester resin, a PPE (polyphenylene ether) resin, and a cyanate ester resin, or a thermoplastic resin can be used.

According to the procedures shown in FIGS. 5B to 5F, a printed wiring board was produced. A release film 1 was a laminate that included a polymer film, i.e., a PET (polyethylene terephthalate) film having a thickness of about 20 μm and a silicone release layer formed on one side of the polymer film. A copper foil was used as a metal foil 5. The compression conditions were as follows: a press temperature of 200° C., a pressure of 50 kg/cm², and a compression time of 60 minutes.

In addition to the conductive particles shown in FIGS. 1 to 3, other conductive particles were prepared by appropriately adjusting the deformation degree. Then, printed wiring boards were produced by using these conductive particles to measure a substrate resistance (Samples 1 to 8). Moreover, spherical conductive particles also were used without deformation (Samples 9 and 10). The spherical conductive particles in Sample 9 were not smoothed, while those in Sample 10 were smoothed.

The deformation degree, specific surface area, and average diameter of the conductive particles and the paste viscosity and substrate resistance of the printed wiring board were measured for each sample.

Both the deformation degree and the average diameter were determined by the laser diffraction method as described above. The specific surface area was determined by a single-point BET method with a specific surface area meter that uses nitrogen as an adsorbate. The paste viscosity was determined with an E-type viscometer under the conditions of ordinary temperatures and 0.5 rpm.

The substrate resistance is a series resistance of 500 via hole conductors, each having a hole diameter of 100 μm, and includes a wiring resistance of 0.7Ω.

For Samples 1 to 7, the concentration of absorbed water of the conductive particles was not more than 1000 ppm. The concentration of absorbed water was determined in such a manner that the conductive particles were heated to 400° C. and the amount of water was measured with a Karl Fischer moisture meter. For Sample 8, a rise in the concentration of absorbed water was attributed to a long process time.

For Samples 1 to 8, the oxygen concentration of the conductive particles was not more than 1.0 wt %. The oxygen concentration was determined in such a manner that the conductive particles were heated in a crucible and the resultant carbon dioxide was quantified by infrared absorption (based on the Japanese Industrial Standard (JIS) Z 2613).

Table 1 shows these measurements.

TABLE 1

| | | Paste | Specific | Average | Substrate |
|---|---|---|---|---|---|
| | Deformation | viscosity | surface area | diameter | resistance |
| Sample | degree | (Pa.s) | (m²/g) | (μm) | (Ω) |
| 1 | 1.01 | 21 | 0.17 | 5.98 | 2.78 |
| 2 | 1.02 | 22 | 0.20 | 6.04 | 2.55 |
| 3 | 1.05 | 23 | 0.24 | 6.22 | 2.50 |
| 4 | 1.10 | 30 | 0.23 | 6.50 | 2.49 |
| 5 | 1.20 | 35 | 0.26 | 7.11 | 2.48 |
| 6 | 1.40 | 400 | 0.30 | 8.29 | 2.42 |
| 7 | 1.50 | 1000 | 0.50 | 8.88 | 2.43 |
| 8 | 1.60 | 1500 | 0.62 | 9.48 | 4.88 |
| 9 | 1.00 | 90 | 0.19 | 5.92 | 3.25 |
| 10 | 1.00 | 15 | 0.16 | 5.94 | 3.75 |

As shown in Table 1, the flat conductive particles having a deformation degree of not more than 1.50 can achieve a sufficiently low substrate resistance (3Ω or less; ranging from 2.42 to 2.78Ω in Samples 1 to 7). The reason for this is considered to be as follows: a surface contact between the flat conductive particles contributes to a reduction in resistance, while a point contact between the conventional conductive particles that are substantially spherical in shape is used basically to establish electrical conduction.

The deformed conductive particles result from plastic deformation that involves the application of an external stress, and the applied stress is considered to remain in the crystal lattice. The internal stress accumulated inside the crystals can facilitate the rearrangement of atoms by heating and pressing. Thus, for the above example, the internal stress accumulated in the conductive particles may contribute to attaining the aggregation of particles more easily and solidly.

The present invention can provide a conductive paste that includes 30 to 70 vol % of flat conductive particles and 70 to 30 vol % of a binder and has a viscosity of not more than 1000 Pa·s. The conductive particles have, e.g., an average diameter of 0.2 to 20 μm, and preferably not less than 0.5 μm (e.g., 6 to 20 μm), and a specific surface area of 0.05 to 1.5 m²/g, preferably not less than 0.2 m²/g, and more preferably less than 1.0 m²/g. The binder includes a thermosetting resin as the main component.

Another aspect of the present invention is a method for manufacturing a conductive paste that includes deforming conductive particles so that the specific surface area is 0.05 to 1.5 m²/g, and preferably not less than 0.2 m²/g and less than 1.0 m²/g.

As described above, the present invention can provide a conductive paste that easily ensures electrical conduction. This conductive paste makes it possible to maintain a low resistance between the wiring layers even with a prepreg sheet having poor compressibility.

1. A method for manufacturing a conductive paste comprising:
deforming conductive particles so that a deformation degree is 1.01 to 1.5 by application of a stress to the conductive particles; and
mixing the deformed conductive particles with a binder that includes a thermosetting resin as a main component,
wherein the deformation degree is determined by dividing an average diameter of the conductive particles after deformation by an average diameter of the conductive particles before deformation, where the average diameter is measured by a laser diffraction method.

2. The method according to claim 1, wherein the conductive particles are deformed so that a specific surface area is 0.05 m²/g to 1.5 m²/g.

3. The method according to claim 1, wherein the conductive particles are deformed so that an average diameter measured by the laser diffraction method is 0.2 μm to 20 μm.

4. The method according to claim 1, wherein the conductive particles are mixed with the binder so that the conductive particles are 30 to 70 vol % and the binder is 70 to 30 vol %.

5. The method according to claim 1, wherein the conductive particles include at least one selected from the group consisting of gold, platinum, silver, palladium, copper, nickel, tin, lead, indium, zinc, and chromium.

6. The method according to claim 1, wherein the stress is applied to the conductive particles in an organic solvent.

7. The method according to claim 1, further comprising drying the conductive particles in a non-oxidizing atmosphere.

8. A method for manufacturing a printed wiring board comprising:
producing a conductive paste by the method according to claim 1;
forming through holes in a prepreg sheet with a release film attached to at least one surface;
filling the through holes with the conductive paste;
compressing the prepreg sheet along with the release film and the conductive paste; and
removing the release film from the prepreg sheet after compressing the prepreg sheet.

9. The method according to claim 8, wherein the prepreg sheet comprises a reinforcing fiber and a resin, a resin layer that comprises no reinforcing fiber is formed on a surface of the prepreg sheet, and the resin layer has a thickness of 1 μm to 30 μm before compressing the prepreg sheet.
